(19) United States
(12) Patent Application Publication
(10) Pub. No.: US 2026/0068213 A1
(43) Pub. Date: Mar. 5, 2026

(54) Semiconductor Device Having Embedded Epitaxial Layer and Method for Manufacturing the Same

(71) Applicant: Shanghai Huali Integrated Circuit Corporation, Shanghai (CN)

(72) Inventors: Chenxu ZHAO, Shanghai (CN); Peiyu CHEN, Shanghai (CN)

(73) Assignee: Shanghai Huali Integrated Circuit Corporation, Shanghai (CN)

(21) Appl. No.: 19/280,227

(22) Filed: Jul. 25, 2025

(30) Foreign Application Priority Data
Aug. 30, 2024 (CN) 202411215912.0

(51) Int. Cl. H10D 30/60; H10D 30/01; H10D 62/10; H10D 62/13; H10D 62/60; H10D 62/832

(52) U.S. Cl. CPC H10D 30/601; H10D 30/0227; H10D 62/102; H10D 62/124; H10D 62/151; H10D 62/60; H10D 62/832

(57) ABSTRACT

Disclosed is a semiconductor device having an embedded epitaxial layer, each side surface of a source-drain trench in each source-drain formation region between gate structures has a tip, and there is a first spacing between a plane where the tip is located and a top surface of the source-drain trench. The source-drain trench is filled with the embedded epitaxial layer. The first spacing for the tip in each source-drain formation region is less than or equal to the thickness of an inversion layer on a surface of a channel region at the bottom of the gate structure, and a lowest position of a top surface of a body layer of the embedded epitaxial layer in each source-drain formation region is higher than the top surface of the source-drain trench. Further disclosed is a method for manufacturing a semiconductor device having an embedded epitaxial layer.

### CROSS-REFERENCES TO RELATED APPLICATIONS

This application claims priority to Chinese patent application No. 202411215912.0, filed on Aug. 30, 2024, the disclosure of which is incorporated herein by reference in its entirety.

### TECHNICAL FIELD

The present disclosure relates to a semiconductor device having an embedded epitaxial layer, and in particular, to a method for manufacturing a semiconductor device having an embedded epitaxial layer.

### BACKGROUND

An embedded epitaxial layer is generally used in an existing ultra low leakage (ULL) product, for example, a PMOS transistor in the ULL product generally adopts an embedded SiGe epitaxial layer. The ULL product has a high requirement for the leakage of the device. With the shrinkage of the process technology node, at a small process node, it is likely to present a curve of the leakage of the ULL product rising with the increase of a contact width (thru-W) of an active region between gate structures. The rising trend makes a leakage of a large-sized semiconductor device severe, thus affecting product performance and yield. The active region between the gate structures is a source-drain formation region.

FIG. 1 is a schematic structural diagram of an existing PMOS transistor having an embedded SiGE epitaxial layer. The existing PMOS transistor having an embedded SiGE epitaxial layer includes:
a plurality of gate structures 102 formed on a top surface of a semiconductor substrate, e.g., a silicon substrate 101, where each gate structure 102 includes a gate dielectric layer and a gate conductive material layer stacked in sequence.

A top covering layer 103 is also included at the top of the gate structure 102, and a sidewall 104 is formed on a side surface of the gate structure 102.

The embedded SiGe epitaxial layer is formed in a source-drain trench 105.

The source-drain trench 105 is typically defined using the sidewalls 104 on side surfaces of adjacent gate structures 102 in a self-aligned manner, and has a Σ-shape as shown in FIG. 1 which is obtained by dry etch and a single wet etch with etch rates varying in various crystal orientations.

The embedded SiGe epitaxial layer includes the following:

The embedded epitaxial layer includes a buffer layer 106, a body layer 107 and a cap layer 108.

The buffer layer 106 includes a first buffer layer 1061 and a second buffer layer 1062 stacked in sequence.

The first buffer layer 1061 is of an undoped structure.

The second buffer layer 1062 is subjected to P-type doping. Both the body layer 107 and the cap layer 108 are subjected to heavy P-type doping, and a concentration of the P-type doping of the cap layer 108 is greater than a concentration of the P-type doping of the body layer 107. A concentration of the P-type doping of the second buffer layer 1062 is less than the concentration of the P-type doping of the body layer 107.

Impurities for P-type heavy doping of a source region and a drain region of each semiconductor device include impurities for P-type heavy doping of the embedded epitaxial layer on two sides of the corresponding gate structure 102, respectively. The impurities for the P-type heavy doping of the source region and the drain region of each semiconductor device mainly include impurities for the P-type doping of the cap layer 108.

FIG. 2 is a diagram of a test curve of a leakage current of an existing PMOS transistor having an embedded SiGE epitaxial layer that varies with the increase of a contact width. A curve 201 is a test curve of a leakage current varying with the increase of the contact width of the existing semiconductor device having the embedded epitaxial layer as shown in FIG. 1. In FIG. 2, the width of the horizontal coordinate is the contact width, i.e., thru-W, and the vertical coordinate is the leakage current, i.e., IOFF.

It can be seen that as thru-W increases, IOFF also increases. Therefore, following the trend of the increase of thru-W, the defect of the leakage current, i.e., IOFF, going beyond the range of a required value is bound to occur in a large-sized device.

Currently, in a common method, a device speed is generally slowed down to meet the demand for a leakage of a customer, but an excessively slow device speed may also lead to a low yield in a final test (FT). In FIG. 2, a curve 202 is a curve obtained in a test in which the device speed is slowed down by, for example, 9% on the basis of the curve 201, where slowing down the device speed by 9% may be achieved by decreasing RVP from 0% to −9%. The curve 202 shows an overall decrease in the leakage on the basis of the curve 201, both having the same rising slope. Therefore, how to solve the problem of the leakage increasing with the increase of Thru W without slowing down the device speed is a top priority.

### BRIEF SUMMARY

According to some embodiments in this application, a plurality of semiconductor devices disclosed in this application are simultaneously integrated on the same semiconductor substrate, each semiconductor device having an embedded epitaxial layer comprising: a gate structure, and the gate structure is formed on a top surface of the semiconductor substrate.

A channel region subjected to doping of a second conductivity type is formed at the bottom of the gate structure, and an inversion layer is formed on a surface of the channel region when the semiconductor device is on.

A region between the gate structures is a source-drain formation region, and the width of the source-drain formation region is a contact width.

Each source-drain formation region includes a source-drain trench, each side surface of the source-drain trench has a tip, and there is a first spacing between a plane where the tip is located and a top surface of the source-drain trench.

The source-drain trench is filled with the embedded epitaxial layer.

The embedded epitaxial layer includes a buffer layer, a body layer, and a cap layer.

The buffer layer includes an undoped structure, both the body layer and the cap layer are subjected to heavy doping of a first conductivity type, and a concentration of doping of the first conductivity type of the cap layer is greater than a concentration of doping of the first conductivity type of the body layer.

Impurities for heavy doping of the first conductivity type of a source region and a drain region of each semiconductor device include impurities for heavy doping of the first conductivity type of the embedded epitaxial layer on two sides of the corresponding gate structure, respectively.

The first spacing for the tip in each source-drain formation region is less than or equal to the thickness of the inversion layer, and a lowest position of a top surface of the body layer in each source-drain formation region is higher than the top surface of the source-drain trench.

In some cases, the width of the source-drain trench gradually increases from top to bottom between the top surface of the source-drain trench and the plane where the tip is located; the width of the source-drain trench gradually decreases from top to bottom between a bottom surface of the source-drain trench and the plane where the tip is located.

A side surface of the body layer is perpendicular to the top surface of the source-drain trench.

At the top surface of each source-drain trench, there is a second spacing greater than 0 nm between a side surface of the source-drain trench and the side surface of the body layer, and in the source-drain trench, the undoped structure of the buffer layer completely covers the body layer.

In some cases, the buffer layer includes a first buffer layer and a second buffer layer stacked in sequence.

The first buffer layer is formed on an inner side surface of the source-drain trench.

The second buffer layer is formed on a top surface of the first buffer layer.

The first buffer layer is of an undoped structure.

The second buffer layer is subjected to doping of the first conductivity type, and a concentration of doping of the first conductivity type of the second buffer layer is less than a concentration of doping of the first conductivity type of the body layer.

In some cases, the semiconductor device is a PMOS transistor, the first conductivity type is the P type, and the second conductivity type is the N type.

In some cases, the first buffer layer is a SiGe layer, the second buffer layer is a SiGe layer, the body layer is a SiGe layer, and the cap layer is a Si layer.

A Ge content of the second buffer layer is greater than a Ge content of the first buffer layer, and a Ge content of the body layer is greater than the Ge content of the second buffer layer.

In some cases, each gate structure includes a gate dielectric layer and a gate conductive material layer stacked in sequence, and a sidewall is also formed on a side surface of the gate structure.

A top opening of each source-drain trench is defined by side surfaces of the sidewalls of the gate structure on two sides in a self-aligned manner.

Each source-drain trench has a Σ shape.

In some cases, the contact width has a plurality of values; concentrations of doping of the first conductivity type of the source region and the drain region of each semiconductor device are the same, and the concentration of doping of the first conductivity type of the source region and the drain region of each semiconductor device ensures that a leakage current of the semiconductor device with the maximum contact width is reduced as being less than a specified value.

In some cases, the thickness of the inversion layer is less than 10 nm.

According to some embodiments in this application, a method for manufacturing a semiconductor device having an embedded epitaxial layer is disclosed in the following steps:
step I: providing a semiconductor substrate, and forming a gate structure on a top surface of the semiconductor substrate in a gate formation region of each semiconductor device, where
a channel region subjected to doping of a second conductivity type is formed at the bottom of the gate structure, and an inversion layer is formed on a surface of the channel region when the semiconductor device is on;
a region between the gate structures is a source-drain formation region, and the width of the source-drain formation region is a contact width;
step II: forming a source-drain trench in each source-drain formation region, and adjusting the magnitude of a first spacing, where
each side surface of the source-drain trench has a tip, the first spacing is a distance between a plane where the tip is located and a top surface of the source-drain trench, and the first spacing for the tip in each source-drain formation region is less than or equal to the thickness of the inversion layer; and
step III: filling the source-drain trench with the embedded epitaxial layer.

The embedded epitaxial layer includes a buffer layer, a body layer, and a cap layer; the buffer layer includes an undoped structure, both the body layer and the cap layer are subjected to heavy doping of a first conductivity type, and a concentration of doping of the first conductivity type of the cap layer is greater than a concentration of doping of the first conductivity type of the body layer.

The first spacing further ensures that a lowest position of a top surface of the body layer in each source-drain formation region is higher than the top surface of the source-drain trench.

Impurities for heavy doping of the first conductivity type of a source region and a drain region of each semiconductor device include impurities for heavy doping of the first conductivity type of the embedded epitaxial layer on two sides of the corresponding gate structure, respectively.

In some cases, the width of the source-drain trench gradually increases from top to bottom between the top surface of the source-drain trench and the plane where the tip is located; the width of the source-drain trench gradually decreases from top to bottom between a bottom surface of the source-drain trench and the plane where the tip is located.

A side surface of the body layer is perpendicular to the top surface of the source-drain trench.

At the top surface of each source-drain trench, there is a second spacing greater than 0 nm between a side surface of the source-drain trench and the side surface of the body layer, and in the source-drain trench, the undoped structure of the buffer layer completely covers the body layer.

In some cases, the buffer layer includes a first buffer layer and a second buffer layer stacked in sequence.

The first buffer layer is formed on an inner side surface of the source-drain trench.

The second buffer layer is formed on a top surface of the first buffer layer.

The first buffer layer is of an undoped structure.

The second buffer layer is subjected to doping of the first conductivity type, and a concentration of doping of the first conductivity type of the second buffer layer is less than a concentration of doping of the first conductivity type of the body layer.

In some cases, the semiconductor device is a PMOS transistor, the first conductivity type is the P type, and the second conductivity type is the N type.

In some cases, the first buffer layer is a SiGe layer, the second buffer layer is a SiGe layer, the body layer is a SiGe layer, and the cap layer is a Si layer.

A Ge content of the second buffer layer is greater than a Ge content of the first buffer layer, and a Ge content of the body layer is greater than the Ge content of the second buffer layer.

In some cases, each gate structure includes a gate dielectric layer and a gate conductive material layer stacked in sequence, and a sidewall is also formed on a side surface of the gate structure.

A top opening of each source-drain trench is defined by side surfaces of the sidewalls of the gate structure on two sides in a self-aligned manner.

Each source-drain trench has a Σ shape.

In some cases, the thickness of the inversion layer is less than 10 nm.

In some cases, in step II, a leakage of the corresponding semiconductor device is reduced by reducing the first spacing and simultaneously improving channel conductivity of the semiconductor device.

In some cases, the contact width has a plurality of values; in step III, concentrations of doping of the first conductivity type of the source region and the drain region of each semiconductor device are the same, the leakage of each semiconductor device is reduced by reducing the concentration of doping of the first conductivity type of the source region and the drain region of each semiconductor device, and the concentration of doping of the first conductivity type of the source region and the drain region of each semiconductor device ensures that a leakage current of the semiconductor device with the maximum contact width is reduced as being less than a specified value.

In the present disclosure, the magnitude of the first spacing between the plane where the tip of the source-drain trench in the source-drain formation region is located and the top surface of the source-drain trench is set to be less than or equal to the thickness of the inversion layer and ensure that the lowest position of the top surface of the body layer in each source-drain formation region is higher than the top surface of the source-drain trench.

The first spacing being less than or equal to the thickness of the inversion layer can increase the stress of the embedded epitaxial layer on the inversion layer in the channel region, making it possible to improve the mobility of carriers in the inversion layer, thereby improving the device performance, such as channel conductivity.

Since the top surface of the body layer can be raised after the first spacing is reduced, the provision of the first spacing may ensure that the lowest position of the top surface of the body layer in each source-drain formation region is higher than the top surface of the source-drain trench, making it possible to increase a spacing between the cap layer with a high doping concentration and the channel region, reducing the diffusion of impurities of the first conductivity type into the channel region, and thereby reducing leak paths generated by the diffusion of impurities of the first conductivity type into the channel region. Therefore, with the present disclosure, the leakage of the device can also be reduced by reducing the first spacing.

With the present disclosure, the concentration of doping of the first conductivity type of the source region and the drain region may be further reduced on the basis of adjusting the first spacing, thereby further reducing the number of impurities of the first conductivity type diffusing into the channel region. The concentration of doping of the first conductivity type of the source region and the drain region of the semiconductor device is set as ensuring that the leakage current of the semiconductor device with the maximum contact width is reduced as being less than the specified value, so as to avoid the defect of a large leakage in the case of a rather large contact width, so that the leakage in the cases of various contact widths is reduced as meeting the requirement and does not increase with the increase of the contact width. In this way, leakages of the semiconductor devices with various contact widths are relatively small and have the same magnitude.

### BRIEF DESCRIPTION OF THE DRAWINGS

The present disclosure is further described in detail below with reference to the drawings and specific embodiments:

FIG. 1 is a schematic structural diagram of an existing PMOS transistor having an embedded SiGE epitaxial layer;

FIG. 2 is a diagram of a test of a leakage current of an existing PMOS transistor having an embedded SiGE epitaxial layer that varies with the increase of a contact width.

FIG. 3 is a schematic structural diagram of a semiconductor device having an embedded epitaxial layer according to an embodiment of the present disclosure; and

FIG. 4 is a diagram of a test of a leakage current of a semiconductor device having an embedded epitaxial layer that varies with the increase of a contact width according to an embodiment of the present disclosure.

### DETAILED DESCRIPTION OF THE DISCLOSURE

The technical solutions of the embodiments of the present disclosure are obtained on the basis of an in-depth analysis on the cause of the technical problem of the existing technical solution. Before detailed description of the technical solutions of the embodiments of the present disclosure, the applicant has explained as follows the cause of a leakage of an existing PMOS transistor having an embedded SiGE epitaxial layer as shown in FIG. 1 increasing with the increase of Thru-W.

Referring to FIG. 1, the source-drain trench 105 has a tip, and there is a spacing SMD between a plane where the tip is located and a top surface of the source-drain trench 105. If a top opening of the source-drain trench 105 is enlarged, the spacing SMD is increased under the same etching process condition. In FIG. 1, a dashed line AA represents the plane where the tip is located, and a dashed line BB represents the top surface of the source-drain trench 105.

At the same time, a top surface of the body layer 107 for filling is lowered as Thru-W increases. In FIG. 1, RH represents the thickness of the body layer 107 located above the top surface of the source-drain trench 105. That is, RH decreases as Thru-W increases. Moreover, typically, the top surface of the body layer 107 is not flat, and when RH of a middle region is still a positive value, RH of an edge region of the source-drain trench 105 may be 0 or a negative value, i.e., the top surface of the body layer 107 is level with or lower than the top surface of the source-drain trench 105. In this case, the cap layer 108 is close to the channel region, such that B impurities for heavy doping of the cap layer 108 tend to diffuse into the channel region, as shown by the arrow line corresponding to a mark 109, and more B impurities diffuse into the channel region as Thru-W increases. Since the channel region is subjected to N-type doping, a leak path is generated after the P-type B impurities diffuse into the channel region, and the increase of the leak paths causes an increase of a leakage current.

Further, referring to FIG. 1, the first buffer layer 1061 and the second buffer layer 1062 are separated from each other by a dashed line. It can be seen that, as Thru-W increases, the first buffer layer 1061 fails to cover all side surfaces of the source-drain trench 105, particularly a top corner region of the source-drain trench 105, so that the body layer 107 or the cap layer 108 tends to come into contact with the side surface at the top corner region of the source-drain trench 105, further increasing diffusion of B impurities, and thus further increasing the leakage current.

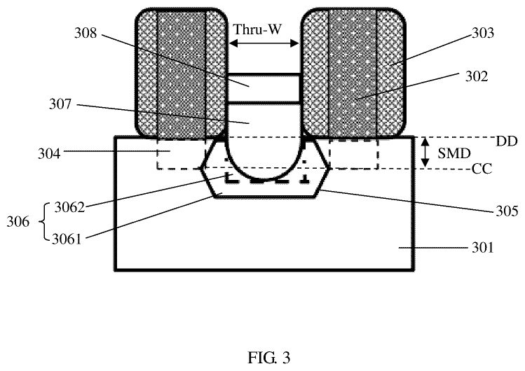

FIG. 3 is a schematic structural diagram of a semiconductor device having an embedded epitaxial layer according to an embodiment of the present disclosure. In the semiconductor device having an embedded epitaxial layer according to this embodiment of the present disclosure, a plurality of semiconductor devices are simultaneously integrated on the same semiconductor substrate 301.

Each semiconductor device includes a gate structure 302, and the gate structure 302 is formed on a top surface of the semiconductor substrate 301. Three gate structures 302 are shown in FIG. 3, one gate structure 302 corresponding to one semiconductor device.

In this embodiment of the present disclosure, each gate structure 302 includes a gate dielectric layer (not shown) and a gate conductive material layer (not shown) stacked in sequence. A sidewall 303 is also formed on the side surface of the first gate structure 302.

A channel region subjected to doping of a second conductivity type is formed at the bottom of the gate structure 302. In some embodiments, the semiconductor substrate is subjected to doping of a second conductivity type. The channel region directly includes the semiconductor substrate at the bottom of the gate structure 302. The channel region shown in FIG. 3 directly includes the semiconductor substrate at the bottom of the gate structure 302. In other embodiments, a region subjected to doping of the second conductivity type is formed in a surface region of the semiconductor substrate 301, and the channel region includes the region subjected to doping of the second conductivity type at the bottom of the gate structure 302.

An inversion layer 304 is formed on a surface of the channel region when the semiconductor device is on. Since the channel region is subjected to doping of the second conductivity type, carriers of the inversion layer 304 are of a conductivity type opposite the doping type of the channel region, and therefore the carriers of the inversion layer 304 are carriers of the first conductivity type.

In some embodiments, the thickness of the inversion layer 304 is less than 10 nm.

A region between the gate structures 302 is a source-drain formation region, the width of the source-drain formation region is a contact width Thru-W, and the contact width Thru-W has a plurality of values. Only one source-drain formation region is shown in FIG. 3, and therefore only one contact width Thru-W is shown. In practice, a plurality of semiconductor devices are simultaneously integrated on the semiconductor substrate 301, and the contact width Thru-W of each semiconductor device is set according to an actual situation. Therefore, the contact width Thru-W has a plurality of values, and the values of the contact width Thru-W correspond to a plurality of semiconductor devices. In FIG. 3, the contact width Thru-W is a direct spacing between two adjacent sidewalls 303. Generally, a lightly doped drain (LDD) region is also formed at the bottom of the sidewall 303.

Each source-drain formation region 305 includes a source-drain trench, each side surface of the source-drain trench 305 has a tip, and there is a first spacing SMD between a plane where the tip is located and a top surface of the source-drain trench 305. In FIG. 3, a dashed line CC represents the plane where the tip is located, and a dashed line DD represents the top surface of the source-drain trench 305.

In this embodiment of the present disclosure, a top opening of each source-drain trench 305 is defined by side surfaces of the sidewalls 303 of the gate structure 302 on two sides in a self-aligned manner.

The source-drain trench 305 is filled with the embedded epitaxial layer.

The embedded epitaxial layer includes a buffer layer 306, a body layer 307 and a cap layer 308.

The buffer layer 306 includes an undoped structure, both the body layer 307 and the cap layer 308 are subjected to heavy doping of the first conductivity type, and a concentration of doping of the first conductivity type of the cap layer 308 is greater than a concentration of doping of the first conductivity type of the body layer 307.

In this embodiment of the present disclosure, the buffer layer 306 includes a first buffer layer 3061 and a second buffer layer 3062 stacked in sequence.

The first buffer layer 3061 is formed on an inner side surface of the source-drain trench 305.

The second buffer layer 3062 is formed on a top surface of the first buffer layer 3061.

The first buffer layer 3061 is of an undoped structure.

The second buffer layer 3062 is subjected to doping of the first conductivity type, and a concentration of doping of the first conductivity type of the second buffer layer 3062 is less than a concentration of doping of the first conductivity type of the body layer 307.

Impurities for heavy doping of the first conductivity type of a source region and a drain region of each semiconductor device include impurities for heavy doping of the first conductivity type of the embedded epitaxial layer on two sides of the corresponding gate structure 302, respectively. Impurities for the heavy doping of the first conductivity type of the source region and the drain region of each semiconductor device mainly include impurities for the doping of the first conductivity type of the cap layer 308.

The first spacing SMD for the tip in each source-drain formation region is less than or equal to the thickness of the inversion layer 304, and a lowest position of a top surface of the body layer 307 in each source-drain formation region is higher than the top surface of the source-drain trench 305. The top surface of the body layer 307 shown in FIG. 3 is a flat surface. However, in practice, the top surface of the body layer 307 has some fluctuations. The closer to the middle region of the source-drain trench 305, the higher the top surface of the body layer 307, and the closer to the edge region of the source-drain trench 305, the lower the top surface of the body layer 307.

In this embodiment of the present disclosure, the width of the source-drain trench 305 gradually increases from top to bottom between the top surface of the source-drain trench 305 and the plane where the tip is located; and the width of the source-drain trench 305 gradually decreases from top to bottom between a bottom surface of the source-drain trench 305 and the plane where the tip is located.

In some preferred embodiments, each source-drain trench 305 has a I shape.

A side surface of the body layer 307 is perpendicular to the top surface of the source-drain trench 305.

At the top surface of each source-drain trench 305, there is a second spacing greater than 0 nm between a side surface of the source-drain trench 305 and the side surface of the body layer 307, and in the source-drain trench 305, the undoped structure of the buffer layer 306 completely covers the body layer 307. As shown in FIG. 3, in a plane corresponding to a dashed line DD, the undoped structure of the buffer layer 306, i.e., the first buffer layer 3061, has a transverse width, and therefore can completely cover the body layer 307, so as to prevent impurities of the first conductivity type in the body layer 307 and the cap layer 308 from diffusing from a top corner position of the source-drain trench 305 into the channel region, thereby reducing leak paths and reducing the leakage.

In this embodiment of the present disclosure, the semiconductor device is a PMOS transistor, the first conductivity type is the P type, and the second conductivity type is the N type. In other embodiments, the semiconductor device may be an NMOS transistor, the first conductivity type is the N type, and the second conductivity type is the P type. The description is made below using only the PMOS transistor as an example:

The first buffer layer 3061 is a SiGe layer, the second buffer layer 3062 is a SiGe layer, the body layer 307 is a SiGe layer, and the cap layer 308 is a Si layer.

A Ge content of the second buffer layer 3062 is greater than a Ge content of the first buffer layer 3061, and a Ge content of the body layer 307 is greater than the Ge content of the second buffer layer 3062.

In some embodiments, the first buffer layer 3061 is a SiGe layer with a Ge content of 25% and is undoped; the second buffer layer 3062 is a SiGe layer with a Ge content of 25% to 30%, and the impurity for the P-type doping is usually B, with a B concentration of about 5E19 cm⁻³; and the body layer 307 is a SiGe layer with a Ge content of 30% to 40% and a B concentration about 3E20 cm⁻³; the cap layer 308 has a Ge content of 0 and a B concentration greater than 1E21 cm⁻³.

In this embodiment of the present disclosure, concentrations of doping of the first conductivity type of the source region and the drain region of each semiconductor device are the same, and the concentration of doping of the first conductivity type of the source region and the drain region of each semiconductor device ensures that a leakage current of the semiconductor device with the maximum contact width Thru-W is reduced as being less than a specified value.

In this embodiment of the present disclosure, the magnitude of the first spacing SMD between the plane where the tip of the source-drain trench 305 in the source-drain formation region is located and the top surface of the source-drain trench 305 is set to be less than or equal to the thickness of the inversion layer 304 and ensure that the lowest position of the top surface of the body layer 307 in each source-drain formation region is higher than the top surface of the source-drain trench 305.

The first spacing SMD being less than or equal to the thickness of the inversion layer 304 can increase the stress of the embedded epitaxial layer on the inversion layer 304 in the channel region, making it possible to improve the mobility of carriers in the inversion layer 304, thereby improving the device performance, such as channel conductivity.

Since the top surface of the body layer 307 can be raised after the first spacing SMD is reduced, the provision of the first spacing SMD may ensure that the lowest position of the top surface of the body layer 307 in each source-drain formation region is higher than the top surface of the source-drain trench 305, making it possible to increase a spacing between the cap layer 308 with a high doping concentration and the channel region, reducing the diffusion of impurities of the first conductivity type into the channel region, and thereby reducing leak paths generated by the diffusion of impurities of the first conductivity type into the channel region. Therefore, with the present disclosure, the leakage of the device can also be reduced by reducing the first spacing SMD.

With this embodiment of the present disclosure, the concentration of doping of the first conductivity type of the source region and the drain region may be further reduced on the basis of adjusting the first spacing SMD, thereby further reducing the number of impurities of the first conductivity type diffusing into the channel region. The concentration of doping of the first conductivity type of the source region and the drain region of the semiconductor device is set as ensuring that the leakage current of the semiconductor device with the maximum contact width Thru-W is reduced as being less than the specified value, so as to avoid the defect of a large leakage in the case of a rather large contact width Thru-W, so that the leakage in the cases of various contact widths Thru-W is reduced as meeting the requirement and does not increase with the increase of the contact width Thru-W. In this way, leakages of the semiconductor devices with various contact widths are relatively small and have the same magnitude.

A method for manufacturing a semiconductor device having an embedded epitaxial layer according to this embodiment of the present disclosure includes the following steps:

Step I. A semiconductor substrate 301 is provided, and a gate structure 302 is formed on a top surface of the semiconductor substrate 301 in a gate formation region of each semiconductor device.

A channel region subjected to doping of a second conductivity type is formed at the bottom of the gate structure 302, and an inversion layer 304 is formed on a surface of the channel region when the semiconductor device is on.

In the method of this embodiment of the present disclosure, each gate structure 302 includes a gate dielectric layer (not shown) and a gate conductive material layer (not shown) stacked in sequence. A sidewall 303 is also formed on the side surface of the first gate structure 302.

In the method of some embodiments, the semiconductor substrate is subjected to doping of a second conductivity type. The channel region directly includes the semiconductor substrate at the bottom of the gate structure 302. The channel region shown in FIG. 3 directly includes the semiconductor substrate at the bottom of the gate structure 302. In the method of other embodiments, a region subjected to doping of the second conductivity type is formed in a surface region of the semiconductor substrate 301, and the channel region includes the region subjected to doping of the second conductivity type at the bottom of the gate structure 302.

Since the channel region is subjected to doping of the second conductivity type, carriers of the inversion layer 304 are of a conductivity type opposite the doping type of the channel region, and therefore the carriers of the inversion layer 304 are carriers of the first conductivity type. In an example of the semiconductor device as being a PMOS transistor, the first conductivity type is the P type, the second conductivity type is the N type, and the carriers of the inversion layer 304 are holes.

In the method of some embodiments, the thickness of the inversion layer 304 is less than 10 nm.

A region between the gate structures 302 is a source-drain formation region, the width of the source-drain formation region is a contact width Thru-W, and the contact width Thru-W has a plurality of values.

Step II: A source-drain trench 305 is formed in each source-drain formation region, and the magnitude of a first spacing SMD is adjusted.

Each side surface of the source-drain trench 305 has a tip, the first spacing SMD is a distance between a plane where the tip is located and a top surface of the source-drain trench 305, and the first spacing SMD for the tip in each source-drain formation region is less than or equal to the thickness of the inversion layer 304.

In the method of this embodiment of the present disclosure, the width of the source-drain trench 305 gradually increases from top to bottom between the top surface of the source-drain trench 305 and the plane where the tip is located; and the width of the source-drain trench 305 gradually decreases from top to bottom between a bottom surface of the source-drain trench 305 and the plane where the tip is located.

In the method of some preferred embodiments, each source-drain trench 305 has a shape.

Generally, the source-drain trench 305 is realized by two times of etch. The first time of etch is dry etch, where the dry etch is anisotropic etch, and a side surface of a trench formed by the etch is vertical. The second time of etch is wet etch. In an example of the semiconductor substrate 301 as being a silicon substrate, a wet etchant may be tetramethylammonium hydroxide (TMAH), so that an etch rate varies in different crystal orientations, thereby expanding the trench into the source-drain trench 305 having a I shape.

In the method of this embodiment of the present disclosure, a top opening of each source-drain trench 305 is defined by side surfaces of the sidewalls 303 of the gate structure 302 on two sides in a self-aligned manner. That is, the width of the top opening of the source-drain trench 305 is determined by the contact width Thru-W. Since the source-drain trench 305 is formed using the same etch process, an etch load varies as the width of the top opening of the source-drain trench 305 varies, resulting in different etch depths. Generally, under the same etch condition, the larger the width of the top opening of the source-drain trench 305, the deeper the depth of the source-drain trench 305.

Step III: The source-drain trench 305 is filled with the embedded epitaxial layer.

The embedded epitaxial layer includes a buffer layer 306, a body layer 307, and a cap layer 308; the buffer layer 306 includes an undoped structure, both the body layer 307 and the cap layer 308 are subjected to heavy doping of a first conductivity type, and a concentration of doping of the first conductivity type of the cap layer 308 is greater than a concentration of doping of the first conductivity type of the body layer 307.

In the method of this embodiment of the present disclosure, the buffer layer 306 includes a first buffer layer 3061 and a second buffer layer 3062 stacked in sequence.

The first buffer layer 3061 is formed on an inner side surface of the source-drain trench 305.

The second buffer layer 3062 is formed on a top surface of the first buffer layer 3061.

The first buffer layer 3061 is of an undoped structure.

The second buffer layer 3062 is subjected to doping of the first conductivity type, and a concentration of doping of the first conductivity type of the second buffer layer 3062 is less than a concentration of doping of the first conductivity type of the body layer 307.

Impurities for heavy doping of the first conductivity type of a source region and a drain region of each semiconductor device include impurities for heavy doping of the first conductivity type of the embedded epitaxial layer on two sides of the corresponding gate structure 302, respectively. Impurities for the heavy doping of the first conductivity type of the source region and the drain region of each semiconductor device mainly include impurities for the doping of the first conductivity type of the cap layer 308.

The first spacing SMD further ensures that a lowest position of a top surface of the body layer 307 in each source-drain formation region is higher than the top surface of the source-drain trench 305. In this way, the cap layer 308 with the highest doping concentration may be prevented from coming close to the channel region, preventing impurities of the first conductivity type in the cap layer 308 that are generated on the right side from diffusing into the channel region, thereby reducing leak paths generated on the right side.

Impurities for heavy doping of the first conductivity type of a source region and a drain region of each semiconductor device include impurities for heavy doping of the first conductivity type of the embedded epitaxial layer on two sides of the corresponding gate structure 302, respectively.

A side surface of the body layer 307 is perpendicular to the top surface of the source-drain trench 305.

In at least the source-drain formation region corresponding to the contact width Thru-W having a maximum value, at the top surface of the source-drain trench 305, there is a second spacing greater than 0 nm between a side surface of the source-drain trench 305 and the side surface of the body layer 307, and in the source-drain trench 305, the undoped structure of the buffer layer 306 completely covers the body layer 307. The undoped structure of the buffer layer 306 that completely covers the body layer 307 can further prevent impurities of the second conductivity type in the body layer 307 and the cap layer 308 from diffusing from into the channel region.

In the method of this embodiment of the present disclosure, the buffer layer 306 includes a first buffer layer 3061 and a second buffer layer 3062 stacked in sequence.

The first buffer layer 3061 is formed on an inner side surface of the source-drain trench 305.

The second buffer layer 3062 is formed on a top surface of the first buffer layer 3061.

The first buffer layer 3061 is of an undoped structure.

The second buffer layer 3062 is subjected to doping of the first conductivity type, and a concentration of doping of the first conductivity type of the second buffer layer 3062 is less than a concentration of doping of the first conductivity type of the body layer 307.

In the method of this embodiment of the present disclosure, the semiconductor device is a PMOS transistor, the first conductivity type is the P type, and the second conductivity type is the N type. In the method of other embodiments, the semiconductor device may be an NMOS transistor, the first conductivity type is the N type, and the second conductivity type is the P type. The description is made below using only the PMOS transistor as an example:

The first buffer layer 3061 is a SiGe layer, the second buffer layer 3062 is a SiGe layer, the body layer 307 is a SiGe layer, and the cap layer 308 is a Si layer.

A Ge content of the second buffer layer 3062 is greater than a Ge content of the first buffer layer 3061, and a Ge content of the body layer 307 is greater than the Ge content of the second buffer layer 3062.

In the method of this embodiment of the present disclosure, in step II, a leakage of the corresponding semiconductor device is reduced by reducing the first spacing SMD and simultaneously improving channel conductivity of the semiconductor device. That is, when the semiconductor device has a large leakage, the first spacing SMD may be further reduced, and the reduction of the first spacing SMD may not only reduce the leakage, but also further improve the device performance. This is mainly achieved by increasing the stress of the channel region and thus increasing the mobility of carriers in the channel.

In step III, concentrations of doping of the first conductivity type of the source region and the drain region of each semiconductor device are the same, the leakage of each semiconductor device is reduced by reducing the concentration of doping of the first conductivity type of the source region and the drain region of each semiconductor device, and the concentration of doping of the first conductivity type of the source region and the drain region of each semiconductor device ensures that a leakage current of the semiconductor device with the maximum contact width Thru-W is reduced as being less than a specified value. In the method of this embodiment of the present disclosure, the width of the opening of the source-drain trench 305 is defined by the contact width Thru-W. Since the source-drain trenches 305 of various widths are formed using the same etch process, the source-drain trench 305 with a largest opening has a maximum etch depth, and correspondingly, the spacing between the cap layer 308 and the channel region is minimum, making it easiest to diffuse impurities of the first conductivity type into the channel region. Therefore, by reducing the doping concentration of the source region and the drain region of the semiconductor device such that a leakage current of a semiconductor device corresponding to the source-drain trench 305 with the largest opening meets the requirement, a leakage current of a semiconductor device corresponding to the source-drain trench 305 with a smaller opening also meets the requirement.

Therefore, in the method of this embodiment of the present disclosure, the leakage of the device may be reduced and the performance of the device may be guaranteed in two ways, i.e., reducing the first spacing SMD and reducing the doping concentration of the source region and the drain region of each semiconductor device. Finally, the leakages of the semiconductor devices corresponding to various contact widths Thru-W all may be caused to meet the requirement, and the leakage does not rise with the increase of the contact width Thru-W of the semiconductor device.

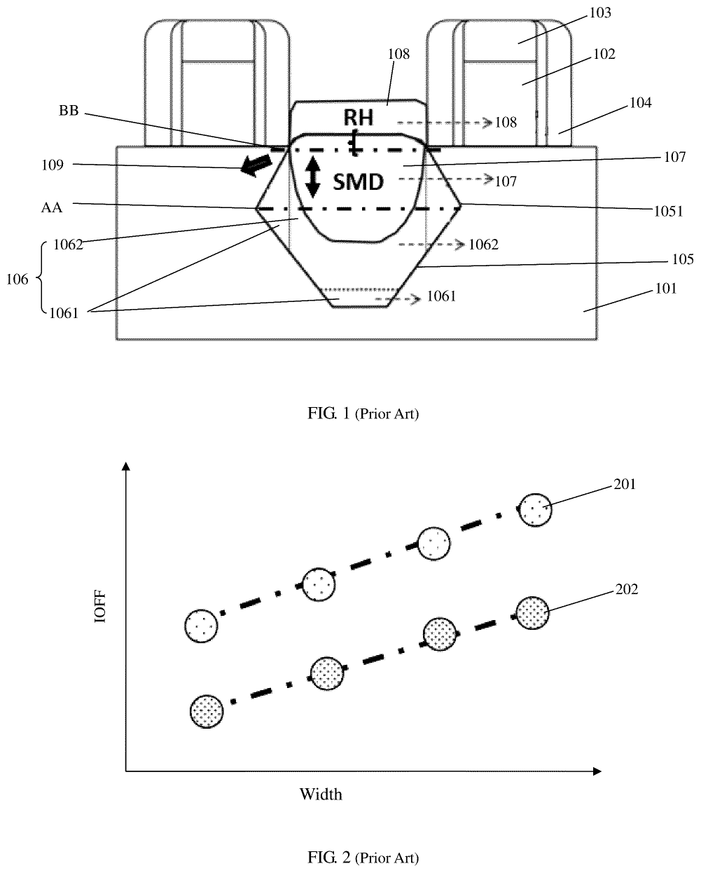

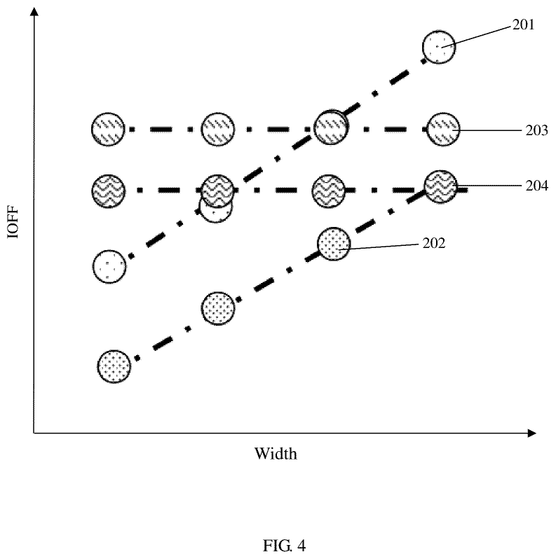

FIG. 4 is a diagram of a test of a leakage current of a semiconductor device having an embedded epitaxial layer that varies with the increase of a contact width according to an embodiment of the present disclosure. In FIG. 4,
a curve 201 is the same as a curve 201 in FIG. 2, both being test curves of the leakage current of the existing semiconductor device having an embedded epitaxial layer that varies with the increase of the contact width;
a curve 202 is the same as a curve 202 in FIG. 2, and is a curve obtained in a test in which the device speed is slowed down by, for example, 9% on the basis of the curve 201, where slowing down the device speed by 9% may be achieved by decreasing RVP from 0% to −9%. The curve 202 shows an overall decrease in the leakage on the basis of the curve 201, both having the same rising slope.

A curve 203 is a test curve of the leakage current varying with the increase of the contact width that is obtained by reducing the concentration of doping of the first conductivity type of the source region and the drain region, such as the B concentration corresponding to the PMOS transistor, on the basis of the existing semiconductor device having an embedded epitaxial layer corresponding to the curve 201. It can be seen that although the leakage does not vary with the increase of the contact width, the leakage is still high and cannot be further reduced, if the B concentration is further reduced, the performance of the device is inevitably affected, for example, the resistance of the source-drain region may increase, and an on-current of the device may decrease.

A curve 204 corresponding to FIG. 4 is a test curve of the leakage current of the semiconductor device having an embedded epitaxial layer in this embodiment of the present disclosure that varies with the increase of the contact width. A curve 204 is a test curve of the leakage current of the semiconductor device having an embedded epitaxial layer in this embodiment of the present disclosure that is obtained by further reducing the first spacing SMD on the basis of the existing semiconductor device having an embedded epitaxial layer corresponding to the curve 203. It can be seen that the reduction of the first spacing SMD may result in a further reduction of the leakage, and the curve 204 is shifted further downward on the basis of the curve 203. It can be seen from the curve 204 that the leakages of the semiconductor devices with various contact widths meet the requirement, and no rising trend occurs.

The present disclosure is described in detail above through specific embodiments, which, however, do not impose limitations to the present disclosure. Without departing from the principle of the present disclosure, a person skilled in the art may also made many other deformations and improvements, which should also be considered as the protection scope of the present disclosure.

What is claimed is:

1. A semiconductor device having an embedded epitaxial layer, wherein a plurality of semiconductor devices are simultaneously integrated on a same semiconductor substrate;
each semiconductor device comprises a gate structure, and the gate structure is formed on a top surface of the semiconductor substrate;
a channel region subjected to doping of a second conductivity type is formed at a bottom of the gate structure, and an inversion layer is formed on a surface of the channel region when the semiconductor device is on;
a region between gate structures is a source-drain formation region, and a width of the source-drain formation region is a contact width;
each source-drain formation region comprises a source-drain trench, each side surface of the source-drain trench has a tip, and there is a first spacing between a plane where the tip is located and a top surface of the source-drain trench;
the source-drain trench is filled with the embedded epitaxial layer;
the embedded epitaxial layer comprises a buffer layer, a body layer, and a cap layer;
the buffer layer comprises an undoped structure, both the body layer and the cap layer are subjected to heavy doping of a first conductivity type, and a concentration of doping of the first conductivity type of the cap layer is greater than a concentration of doping of the first conductivity type of the body layer;
impurities for heavy doping of the first conductivity type of a source region and a drain region of each semiconductor device comprise impurities for heavy doping of the first conductivity type of the embedded epitaxial layer on two sides of a corresponding gate structure; and
the first spacing for the tip in each source-drain formation region is less than or equal to a thickness of the inversion layer, and a lowest position of a top surface of the body layer in each source-drain formation region is higher than the top surface of the source-drain trench.

2. The semiconductor device having the embedded epitaxial layer according to claim 1, wherein a width of the source-drain trench gradually increases from top to bottom between the top surface of the source-drain trench and the plane where the tip is located; the width of the source-drain trench gradually decreases from top to bottom between a bottom surface of the source-drain trench and the plane where the tip is located;
a side surface of the body layer is perpendicular to the top surface of the source-drain trench; and
at the top surface of each source-drain trench, there is a second spacing greater than 0 nm between a side surface of the source-drain trench and the side surface of the body layer, and in the source-drain trench, the undoped structure of the buffer layer completely covers the body layer.

3. The semiconductor device having the embedded epitaxial layer according to claim 2, wherein the buffer layer comprises a first buffer layer and a second buffer layer stacked in sequence;
the first buffer layer is formed on an inner side surface of the source-drain trench;
the second buffer layer is formed on a top surface of the first buffer layer;
the first buffer layer is of an undoped structure; and
the second buffer layer is subjected to doping of the first conductivity type, and a concentration of doping of the first conductivity type of the second buffer layer is less than a concentration of doping of the first conductivity type of the body layer.

4. The semiconductor device having the embedded epitaxial layer according to claim 3, wherein the semiconductor device is a PMOS transistor, the first conductivity type is a P type, and the second conductivity type is an N type.

5. The semiconductor device having the embedded epitaxial layer according to claim 4, wherein the first buffer layer is a SiGe layer, the second buffer layer is a SiGe layer, the body layer is a SiGe layer, and the cap layer is a Si layer; and a Ge content of the second buffer layer is greater than a Ge content of the first buffer layer, and a Ge content of the body layer is greater than the Ge content of the second buffer layer.

6. The semiconductor device having the embedded epitaxial layer according to claim 4, wherein each gate structure comprises a gate dielectric layer and a gate conductive material layer stacked in sequence, and a sidewall is also formed on a side surface of the gate structure;
a top opening of each source-drain trench is defined by side surfaces of the sidewalls of the gate structure on two sides in a self-aligned manner; and
each source-drain trench has a Σ shape.

7. The semiconductor device having the embedded epitaxial layer according to claim 4, wherein the contact width has a plurality of values; and concentrations of doping of the first conductivity type of the source region and the drain region of each semiconductor device are the same, and the concentration of doping of the first conductivity type of the source region and the drain region of each semiconductor device ensures that a leakage current of the semiconductor device with a maximum contact width is reduced as being less than a specified value.

8. The semiconductor device having the embedded epitaxial layer according to claim 1, wherein the thickness of the inversion layer is less than 10 nm.

9. A method for manufacturing a semiconductor device having an embedded epitaxial layer, comprising the following steps:
step I: providing a semiconductor substrate, and forming a gate structure on a top surface of the semiconductor substrate in a gate formation region of each semiconductor device, wherein
a channel region subjected to doping of a second conductivity type is formed at a bottom of the gate structure, and an inversion layer is formed on a surface of the channel region when the semiconductor device is on;
a region between the gate structures is a source-drain formation region, and a width of the source-drain formation region is a contact width;
step II: forming a source-drain trench in each source-drain formation region, and adjusting a magnitude of a first spacing, wherein
each side surface of the source-drain trench has a tip, the first spacing is a distance between a plane where the tip is located and a top surface of the source-drain trench, and the first spacing for the tip in each source-drain formation region is less than or equal to a thickness of the inversion layer; and
step III: filling the source-drain trench with the embedded epitaxial layer, wherein the embedded epitaxial layer comprises a buffer layer, a body layer, and a cap layer; the buffer layer comprises an undoped structure, both the body layer and the cap layer are subjected to heavy doping of a first conductivity type, and a concentration of doping of the first conductivity type of the cap layer is greater than a concentration of doping of the first conductivity type of the body layer;
the first spacing further ensures that a lowest position of a top surface of the body layer in each source-drain formation region is higher than the top surface of the source-drain trench; and
impurities for heavy doping of the first conductivity type of a source region and a drain region of each semiconductor device comprise impurities for heavy doping of the first conductivity type of the embedded epitaxial layer on two sides of a corresponding gate structure.

10. The method for manufacturing the semiconductor device having the embedded epitaxial layer according to claim 9, wherein a width of the source-drain trench gradually increases from top to bottom between the top surface of the source-drain trench and the plane where the tip is located; the width of the source-drain trench gradually decreases from top to bottom between a bottom surface of the source-drain trench and the plane where the tip is located;
a side surface of the body layer is perpendicular to the top surface of the source-drain trench; and
at the top surface of each source-drain trench, there is a second spacing greater than 0 nm between a side surface of the source-drain trench and the side surface of the body layer, and in the source-drain trench, the undoped structure of the buffer layer completely covers the body layer.

11. The method for manufacturing the semiconductor device having the embedded epitaxial layer according to claim 10, wherein the buffer layer comprises a first buffer layer and a second buffer layer stacked in sequence;
the first buffer layer is formed on an inner side surface of the source-drain trench;
the second buffer layer is formed on a top surface of the first buffer layer;
the first buffer layer is of an undoped structure; and
the second buffer layer is subjected to doping of the first conductivity type, and a concentration of doping of the first conductivity type of the second buffer layer is less than a concentration of doping of the first conductivity type of the body layer.

12. The method for manufacturing the semiconductor device having the embedded epitaxial layer according to claim 11, wherein the semiconductor device is a PMOS transistor, the first conductivity type is a P type, and the second conductivity type is an N type.

13. The method for manufacturing the semiconductor device having the embedded epitaxial layer according to claim 12, wherein the first buffer layer is a SiGe layer, the second buffer layer is a SiGe layer, the body layer is a SiGe layer, and the cap layer is a Si layer; and
a Ge content of the second buffer layer is greater than a Ge content of the first buffer layer, and a Ge content of the body layer is greater than the Ge content of the second buffer layer.

14. The method for manufacturing the semiconductor device having the embedded epitaxial layer according to claim 12, wherein each gate structure comprises a gate dielectric layer and a gate conductive material layer stacked in sequence, and a sidewall is also formed on a side surface of the gate structure;
a top opening of each source-drain trench is defined by side surfaces of the sidewalls of the gate structure on two sides in a self-aligned manner; and
each source-drain trench has a Σ shape.

15. The method for manufacturing the semiconductor device having the embedded epitaxial layer according to claim 9, wherein the thickness of the inversion layer is less than 10 nm.

16. The method for manufacturing the semiconductor device having the embedded epitaxial layer according to claim 12, wherein, in step II, a leakage of a corresponding semiconductor device is reduced by reducing the first spacing and simultaneously improving channel conductivity of the semiconductor device.

17. The method for manufacturing the semiconductor device having the embedded epitaxial layer according to claim 16, wherein the contact width has a plurality of values; and, in step III, concentrations of doping of the first conductivity type of the source region and the drain region of each semiconductor device are the same, the leakage of each semiconductor device is reduced by reducing the concentration of doping of the first conductivity type of the source region and the drain region of each semiconductor device, and the concentration of doping of the first conductivity type of the source region and the drain region of each semiconductor device ensures that a leakage current of the semiconductor device with a maximum contact width is reduced as being less than a specified value.
